(19) United States
(12) Patent Application Publication
(10) Pub. No.: US 2003/0227039 A1
(43) Pub. Date: Dec. 11, 2003

(54) Solid-state image pickup device

(76) Inventors: Tomoyuki Umeda, Kanagawa (JP); Nobuo Nakamura, Kanagawa (JP); Ryoji Suzuki, Kanagawa (JP); Hiroaki Fujita, Kanagawa (JP)

Correspondence Address: ROBERT J. DEPKE LEWIS T. STEADMAN, HOLLAND & KNIGHT LLC, 131 SOUTH DEARBORN, 30TH FLOOR, CHICAGO, IL, 60603, US

(21) Appl. No.: 10/382,054

(22) Filed: Mar. 4, 2003

(30) Foreign Application Priority Data
Mar. 5, 2002 (JP) JP2002-058502

(51) Int. Cl. H01L 31/062

(52) U.S. Cl. 257/291; 257/292

(57) ABSTRACT

A photodiode and a FD portion are arranged in parallel with a transfer gate portion interposed therebetween, and a transfer electrode is arranged above the transfer gate portion. The transfer electrode has a body portion and an expanded portion and is expanded in the gate lengthwise direction. Where the partial expanded portion is provided on the transfer electrode in this manner, the modulation degree of the transfer electrode can be increased while the amount of reduction of the area of a light reception portion of the photodiode is reduced (the numerical aperture is increased). As a result, a solid-state image pickup device with which transfer residual is less likely to occur and which is suitable for complete transfer can be configured.

This application claims priority to Japanese Patent Application Number JP2002-058502 filed Mar. 5, 2002, which is incorporated herein by reference.

This invention relates to a solid-state image pickup device wherein each of a plurality of pixels which form an image pickup region includes a photoelectric conversion element and at least one or more transistors which form a readout circuit for signal charge of the photoelectric conversion element. More particularly, the present invention is directed to improvements in a gate portion of the transistors.

### RELATED ART

A CMOS type solid-state image pickup device is conventionally known which has an image pickup region in which pixels are disposed two-dimensionally on a semiconductor substrate and includes, for each of the pixels, a photodiode (PD) serving as a photoelectric conversion element, a transfer transistor for transferring signal charge produced by the photodiode to a floating diffusion portion (hereinafter referred to as FD portion), an amplification transistor for detecting an amount of the signal charge transferred to the floating diffusion portion and converting the signal charge amount into an electric signal, a selection transistor for selectively signaling an output of the amplification transistor to an output signal line, a reset transistor for resetting the signal charge of the floating diffusion portion, and so forth.

FIG. 17 is a plan view showing an example (first conventional example) of an arrangement of elements around a photodiode in a pixel in such a conventional solid-state image pickup device as described above.

As shown in FIG. 17, a photodiode 10 and a FD portion 12 are disposed in parallel to each other with a transfer gate portion 14 interposed therebetween. A transfer electrode (TG) 14A is disposed above the transfer gate portion 14, and an end portion of the transfer electrode 14A is connected to an upper wiring line (not shown) through a contact 14B.

In such an element arrangement as described above, if a predetermined voltage is applied to the transfer electrode 14A, then signal charge of the photodiode 10 is read out to the FD portion 12 side through a channel region of the transfer gate portion 14.

Meanwhile, FIGS. 18A and 18B are sectional views showing an element structure in a semiconductor substrate in the element arrangement shown in FIG. 17.

As shown in FIGS. 18A and 18B, a P type well region 22 is formed on a semiconductor substrate (N type silicon substrate) 20, and the photodiode 10 is formed from a P+ layer 10A of an upper layer and an N layer 10B of a lower layer.

Further, the FD portion 12 is formed as an N+ region at a position spaced by a predetermined distance from the photodiode 10.

The P type region between the photodiode 10 and the FD portion 12 forms the transfer gate portion 14, and the transfer electrode 14A is disposed on an upper face of the transfer gate portion 14.

It is to be noted that an element isolation region 16 formed from LOCOS or the like is provided around the pixel so that the pixel is electrically isolated from adjacent pixels.

Here, in a state wherein a Low voltage is applied to the transfer electrode 14A to control the transfer gate portion 14 to an OFF state, no channel is formed below the transfer electrode 14A as shown in FIG. 18A, but the portion below the transfer electrode 14A remains as P type.

Then, when a power supply voltage is applied to the transfer electrode 14A to turn the transfer gate portion 14 ON, signal charge 18 accumulates below the transfer electrode 14A as shown in FIG. 17B to form an N type channel.

FIG. 19 is a plan view showing another example (second conventional example) of an arrangement of pixels around a photodiode in a pixel in a conventional solid-state image pickup device (refer to the paper “An Image Sensor with a Simple FPN-reduction Technology and a Hole Accumulated Diode”, ISSCC, (2000)).

In this example, a FD portion 32 is arranged at an oblique position with respect to a photodiode 30, and a transfer gate portion 34 and a transfer gate 34A are arranged in a right-angularly bent state in such a manner that it surrounds two side faces of the FD portion 32.

It is to be noted that an end portion of the transfer gate 34A is connected to an upper wiring line (not shown) through a contact 34B.

Also in such an element arrangement as just described, if a predetermined voltage is applied to the transfer gate 34A, then signal charge of the photodiode 30 is read out to the FD portion 32 side through a channel region of the transfer gate portion 34.

Incidentally, in the first conventional example described above, the channel region of the transfer gate portion 14 has a single gate length (L shown in FIG. 17) (that is, the width in the gate lengthwise direction of the transfer electrode 14A).

However, in the case of such a transfer electrode as described above, since the gate length by the transfer electrode 14A is small, the modulation degree of the transfer electrode 14A is low, and therefore, the potential in a region below the transfer electrode 14A when an applied voltage is turned ON remains low.

Therefore, even if the transfer electrode 14A is turned ON, since the potential in the region below the transfer electrode 14A is lower than the potential of the photodiode, transfer residual wherein signal charge remains in the photodiode occurs.

In other words, full transfer of the signal charge from the photodiode to the FD portion is less likely to occur.

On the contrary if the gate length is great, then in light of the fact that the modulation degree is high, the potential in the region below the transfer electrode when the applied voltage is turned ON can be made high.

Thus, while it is possible to generally increase the width (L1) in the gate widthwise direction of the transfer electrode, only if the width is increased simply, then the numerical aperture of the photodiode decreases and also the saturation signal charge amount decreases (if it is tried to conversely keep the numerical aperture equal, then the device area increases). Particularly with a fine pixel size, a drop of the saturation signal charge amount is a significant problem.

Thus, a technique for increasing the degree of modulation of the transfer electrode while reduction of the area of the photodiode is suppressed has been demanded.

The conventional example shown in FIG. 19 solves such a goal as just described and increases the width in the gate lengthwise direction by forming the transfer electrode such that it has a graphic shape bent at the right angle. In such a transfer electrode as just described, the gate length is equal to √2 times L1, from the theory of right-angled triangle.

However, it is estimated that, as a result of actual lithographic processing, the graphic shape of a corner portion is rounded and the gate length of the corner portion becomes substantially equal to L1.

Further, in the structure of the second conventional example, since the portion having the gate length L1′ is influenced by the opposite sides thereof, some width is required as the gate width of the portion of the increased gate length.

It is to be noted that a similar problem arises not only with a transfer gate but also with other transistors which form a readout circuit in the pixel, for example, a reset gate and so forth.

It is therefore an object of the present invention to provide a solid-state image pickup device which can suppress the influence upon the numerical aperture of a photoelectric conversion element to the minimum and effectively controls the potential at a gate portion of a transfer transistor or a reset transistor to eliminate residual charge by an insufficient degree of potential modulation. Other objects and advantages of the present invention will be apparent in light of the following summary and detailed description.

### SUMMARY OF THE INVENTION

This invention relates to a solid-state image pickup device having a plurality of pixels comprised of a photoelectric conversion element, a transistor formed within said pixel, wherein a gate electrode of said transistor is comprised of structures having a plurality of different widths.

Furthermore, this invention relates to a solid-state image pickup device comprised of a photoelectric conversion portion, a first transistor connected to said photoelectric conversion portion, a second transistor connected to said first transistor, a third transistor connected to a node between said first and second transistors, and wherein at least a gate electrode of one of said first, second and third transistors has a convex or protruding portion.

### BRIEF DESCRIPTION OF THE DRAWINGS

FIG. 1 is a circuit diagram showing an example of a pixel portion for an image pickup device;

FIG. 2 is a plan view showing an example of an arrangement of elements around a photodiode in a pixel of a solid-state image pickup device according to a first exemplary embodiment of the present invention;

FIGS. 3A and 3B are sectional views showing an element structure in a semiconductor substrate in the element arrangement shown in FIG. 2;

FIG. 4 is a diagram illustrating the modulation degree of a solid-state image pickup device which has the element arrangement shown in FIG. 2 in comparison with that of a conventional example;

FIG. 5 is a plan view showing an example of an arrangement of elements around a photodiode in a pixel of a solid-state image pickup device according to a second exemplary embodiment of the present invention;

FIG. 6 is a plan view showing an example of an arrangement of elements around a photodiode in a pixel of a solid-state image pickup device according to a third exemplary embodiment of the present invention;

FIG. 7 is a plan view showing an example of an arrangement of elements around a photodiode in a pixel of a solid-state image pickup device according to a fourth exemplary embodiment of the present invention;

FIG. 8 is a plan view showing an example of an arrangement of elements around a photodiode in a pixel of a solid-state image pickup device according to a fifth exemplary embodiment of the present invention;

FIG. 9 is a plan view showing an example of an arrangement of elements around a photodiode in a pixel of a solid-state image pickup device according to a sixth exemplary embodiment of the present invention;

FIG. 10 is a plan view showing an example of an arrangement of elements around a photodiode in a pixel of a solid-state image pickup device according to a seventh exemplary embodiment of the present invention;

FIG. 11 is a plan view showing an example of an arrangement of elements around a photodiode in a pixel of a solid-state image pickup device according to an eighth exemplary embodiment of the present invention;

FIGS. 12A and 12B are sectional views showing an element structure in a semiconductor substrate in the element arrangement shown in FIG. 11;

FIG. 13 is a plan view showing an example of an arrangement of elements around a photodiode in a pixel of a solid-state image pickup device according to a ninth exemplary embodiment of the present invention;

FIG. 14 is a plan view showing an example of an arrangement of elements around a photodiode in a pixel of a solid-state image pickup device according to a tenth exemplary embodiment of the present invention;

FIG. 15 is a plan view showing an example of an arrangement of elements around a photodiode in a pixel of a solid-state image pickup device according to an eleventh exemplary embodiment of the present invention;

FIG. 16 is a plan view showing an example of an arrangement of elements around a photodiode in a pixel of a solid-state image pickup device according to a twelfth exemplary embodiment of the present invention;

FIG. 17 is a plan view showing an example (first conventional example) of an arrangement of elements around a photodiode in a pixel in a conventional solid-state image pickup device;

FIGS. 18A and 18B are sectional views showing an element structure in a semiconductor substrate in a solid-state image pickup device having the element arrangement shown in FIG. 17; and

FIG. 19 is a plan view showing another example (second conventional example) of an arrangement of elements around a photodiode in a pixel in a conventional solid-state image pickup device.

### DETAILED DESCRIPTION OF THE PREFERRED EXEMPLARY EMBODIMENTS

Various exemplary embodiments of a solid-state image pickup device according to the present invention are described.

It is to be noted that, while the embodiments described below are preferred embodiments of the present invention and the description including various technical details, the scope of the present invention is not limited by the exemplary embodiments unless it is recited in the following description that the present invention is so limited.

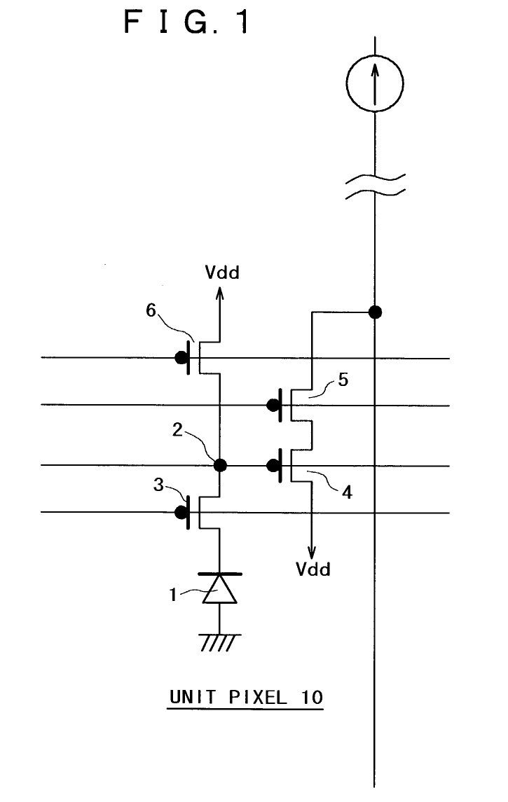

As shown in FIG. 1, in the present embodiments, a CMOS type solid-state image pickup device wherein a semiconductor substrate has an image pickup region 11 in which unit pixels 10 are arranged two-dimensionally and each of the pixels has a photodiode 1 (PD) serving as a photoelectric conversion element, a transfer transistor 3 (transfer gate portion) for transferring signal charge produced by the photodiode to a floating diffusion portion 2 (hereinafter referred to as FD portion), an amplification transistor 4 for detecting an amount of the signal charge transferred to the FD portion and converting the signal charge amount into an electric signal, a selection transistor 5 for selectively signaling an output of the amplification transistor to an output signal line, a reset transistor 6 for resetting the signal charge of the FD portion and so forth is configured such that a transfer gate (TG) of the transfer gate portion provided in each of the pixels in the image pickup region is partially expanded in the gate lengthwise direction to increase the modulation degree by the transfer electrode and to increase the channel potential below the transfer electrode when the transfer is ON thereby to make it possible to read out the signal charge of the photodiode (PD) by complete transfer.

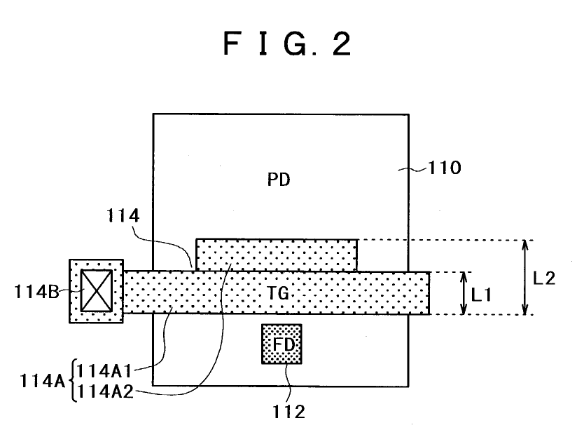

FIG. 2 is a plan view showing an example of an arrangement of elements around a photodiode in a pixel of a solid-state image pickup device according to a first embodiment of the present invention.

As shown in FIG. 2, a photodiode 110 and a FD portion 112 are arranged in parallel to each other with a transfer gate portion 114 interposed therebetween. A transfer electrode 114A formed from a polycrystalline silicon film is arranged above the transfer gate portion 114, and an end portion of the transfer electrode 114A is connected to an upper wiring line (not shown) through a contact 114B.

The transfer electrode 114A in the present example includes a body portion 114A1 and an expanded portion 114A2 extending to the photodiode 110 side and formed integrally with the body portion 114A1.

Each of the body portion 114A1 and the expanded portion 114A2 is formed in a straight belt-like configuration, and the expanded portion 114A2 is provided at a portion approximately one half of the transfer electrode 114A in the gate widthwise direction. The width of the transfer electrode 114A in the gate lengthwise direction is, at a portion thereof at which the expanded portion 114A2 is not provided, L1 of the body portion 114A1, but is expanded, at another portion at which the expanded portion 114A2 is provided, to L2.

It is to be noted that, while the body portion 114A1 and the expanded portion 114A2 are shown distinctly from each other in FIG. 1, actually they are formed from a polycrystalline silicon electrode film of the same layer and an equal driving voltage is applied to them.

In such an element arrangement as described above, if a predetermined voltage is applied to the transfer electrode 114A, then signal charge of the photodiode 110 is read out to the FD portion 112 side through a channel region of the transfer gate portion 114.

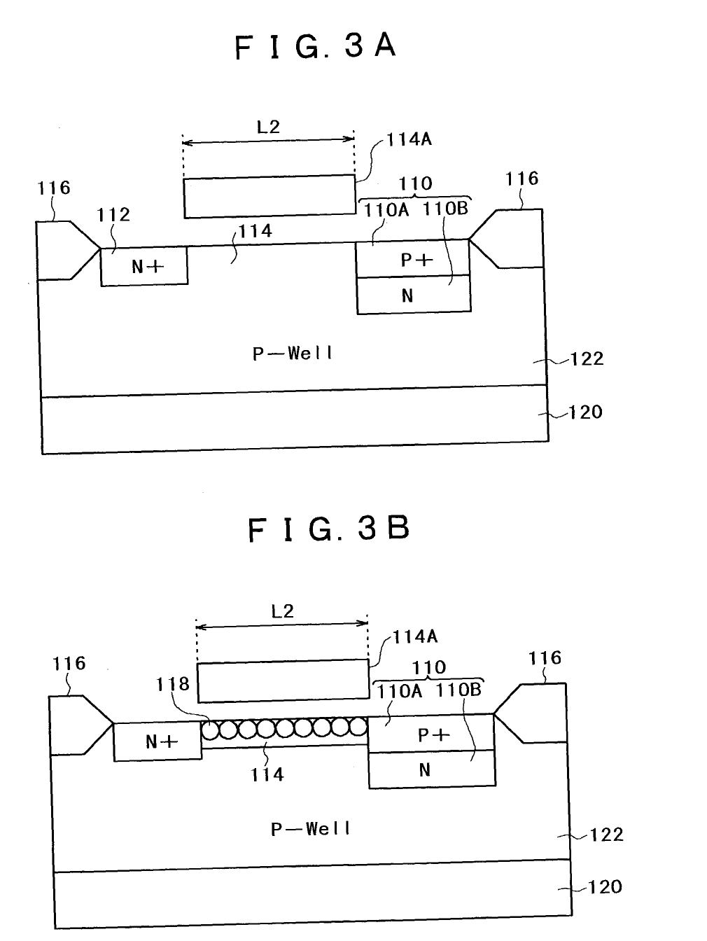

FIGS. 3A and 3B are sectional views showing an element structure in a semiconductor substrate in the element arrangement shown in FIG. 2.

As shown in FIGS. 3A and 3B, a P type well region 122 is formed on a semiconductor substrate (N type silicon substrate) 120, and the photodiode 110 is formed from a P+ layer 110A of an upper layer and an N layer 110B of a lower layer.

Further, the FD portion 112 is formed as an N+ region at a position spaced by a predetermined distance from the photodiode 110.

The P type region between the photodiode 110 and the FD portion 112 is formed as the transfer gate portion 114, and the transfer electrode 114A is arranged on an upper face of the transfer gate portion 114.

It is to be noted that an element isolation region 116 made of LOCOS or the like is provided around the pixel so that the pixel is electrically isolated from adjacent pixels.

Here, in a state wherein a Low voltage is applied to the transfer electrode 114A to place the transfer gate portion 114 to an OFF state, no channel is formed below the transfer electrode 114A as shown in FIG. 3A, but the portion below the transfer electrode 114A remains in the P type.

Then, if a power supply voltage is applied to the transfer electrode 114A to turn the transfer gate portion 114 to an ON state, then signal charge 118 accumulates at a portion below the transfer electrode 114A to form an N type channel as shown in FIG. 3B.

In the present example, the gate length is increased by such a transfer electrode 114A which has the expanded portion 114A2 part thereof as described above.

Operation when the voltage is applied is described specifically herein.

1. First, a power supply voltage is applied to the transfer electrode 114A.

2. Consequently, N type charge is produced at a surface portion (P type) of the FD portion 112 corresponding to the transfer electrode 114A, that is, the transfer gate portion 114.

3. Signal charge accumulates at the surface portion (N type) corresponding to the transfer electrode 114A.

4. A modulation difference occurs simultaneously with the production of the N type and the accumulation of signal charge.

5. Simultaneously when the modulation difference occurs, the signal charge having been in the photodiode (P type) 110 flows into the FD portion (N+ type) 112 through the transfer electrode 114A (N− type).

In such operation as described above, where the partial expanded portion 114A2 is provided for the transfer electrode 114A, it is possible to increase the modulation degree of the transfer electrode 114A while decreasing the amount of reduction of the area of the light reception portion of the photodiode 110 (while increasing the numerical aperture). As a result, a solid-state image pickup device with which transfer residual is less likely to occur and which is suitable for full transfer can be configured.

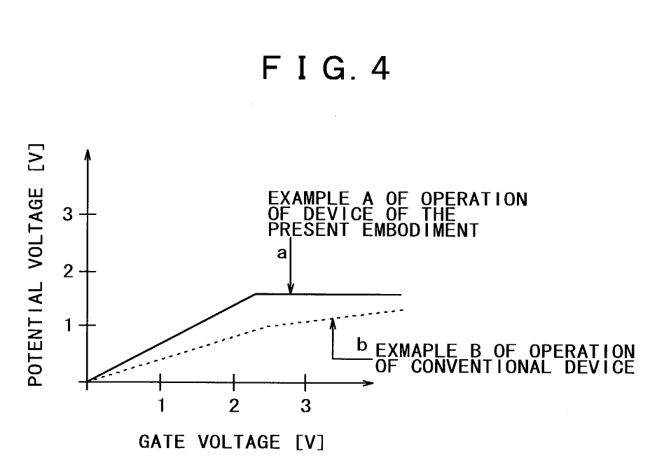

FIG. 4 is a diagram illustrating the modulation degree by the solid-state image pickup device of the present embodiment having such a configuration as described above in comparison with that of the conventional example. The axis of abscissa indicates the gate voltage (V), and the axis of ordinate indicates the potential voltage (V).

As seen in FIG. 4, with the solid-state image pickup device of the present embodiment indicated by a solid line a, a steep potential variation can be obtained with a low gate voltage when compared with the conventional example indicated by a broken line b.

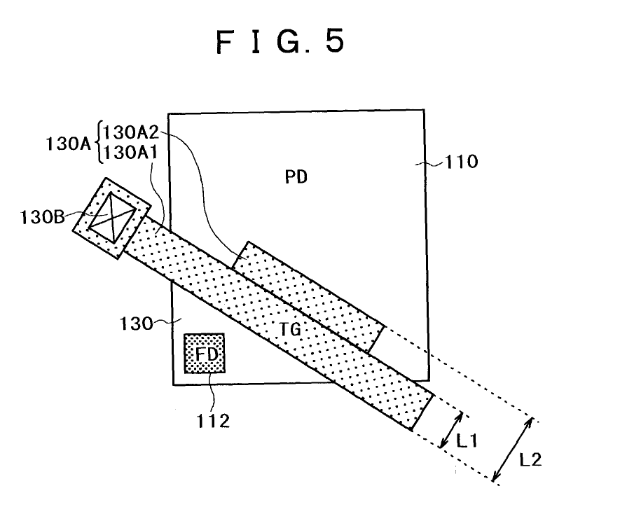

FIG. 5 is a plan view showing an example of an arrangement of elements around a photodiode in a pixel of a solid-state image pickup device according to a second embodiment of the present invention. It is to be noted that elements common to those of the example shown in FIG. 2 are denoted by like reference characters and description thereof is omitted.

The solid-state image pickup device of the present example is configured such that a FD portion 112 is arranged at an oblique position with respect to a photodiode 110 and a transfer electrode 130A of a transfer electrode portion 130 is arranged in an oblique direction.

Further, the transfer electrode 130A in the present example includes a body portion 130A1 and an expanded portion 130A2 each formed in a straight belt-like configuration and provided integrally with each other, and the expanded portion 130A2 is provided at a portion approximately one half of the body portion 130A1. It is to be noted that an end portion of the body portion 130A1 of the transfer electrode 130A is connected to an upper wiring line (not shown) through a contact 130B.

Also in the present example, since the expanded portion 130A2 is provided, the width of the transfer electrode 114A in the gate lengthwise direction is, at a portion thereof at which the expanded portion 130A2 is not provided, L1 of the body portion 130A1, but is expanded, at another portion thereof at which the expanded portion 130A2 is provided, to L2 and the modulation degree by the transfer electrode 130A is increased.

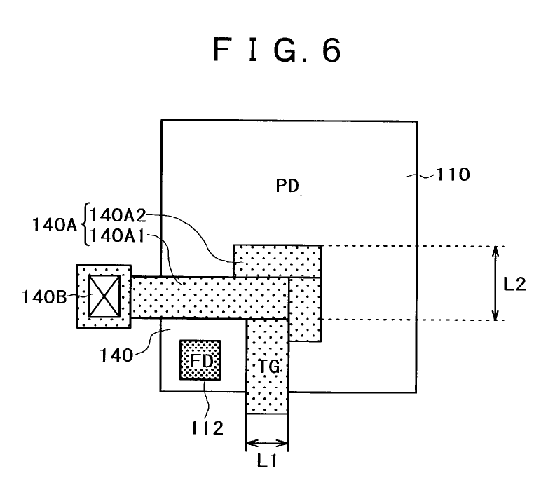

FIG. 6 is a plan view showing an example of an arrangement of elements around a photodiode in a pixel of a solid-state image pickup device according to a third embodiment of the present invention. It is to be noted that elements common to those of the example shown in FIG. 2 are denoted by like reference characters and description thereof is omitted.

The solid-state image pickup device of the present embodiment is configured such that a FD portion 112 is arranged at an oblique position with respect to a photodiode 110 and a transfer electrode 140A of a transfer electrode portion 140 is arranged in a right-angularly bent state such that it surrounds two side faces of the FD portion 112.

Also in the present example, the transfer electrode 140A has a body portion 140A1 and an expanded portion 140A2, and the expanded portion 140A2 is provided integrally at an outer side corner portion of the body portion 140A1 bent at the right angle of 90 degrees.

It is to be noted that an end portion of the body portion 140A1 of the transfer electrode 140A is connected to an upper wiring line (not shown) through a contact 140B.

By such a configuration as described above, the width of the corner portion of the transfer electrode 140A is expanded from “2L1 to “2L2, and the modulation degree by the transfer electrode 140A is increased.

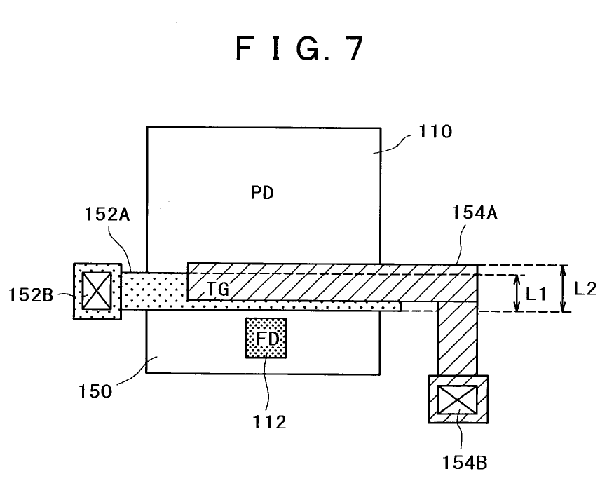

FIG. 7 is a plan view showing an example of an arrangement of elements around a photodiode in a pixel of a solid-state image pickup device according to a fourth embodiment of the present invention. It is to be noted that elements common to those of the example shown in FIG. 2 are denoted by like reference characters and description thereof is omitted.

The solid-state image pickup device of the present embodiment is configured such that two transfer electrodes 152A and 154A of different layers are provided for one gate portion 150 between the photodiode 110 and the FD portion 112. The transfer electrodes 152A and 154A extend to a location above the gate portion 150 from the opposite sides of the gate portion 150, and the transfer electrode 152A arranged on the lower layer is arranged over the overall gate width while the other transfer electrode 154A disposed on the upper layer is arranged up to an intermediate position of the gate width.

It is to be noted that end portions of the transfer electrodes 152A and 154A are connected to upper wiring lines (not shown) through contacts 152B and 154B, respectively.

As the transfer electrodes 152A and 154A are arranged in a state wherein they are displayed by a fixed amount in the gate lengthwise direction, the width in the gate widthwise direction is expanded from L1 in the case wherein only the transfer electrode 152A is involved to L2 in the case wherein the two transfer electrodes 152A and 154A are involved, and the modulation degree by the transfer electrodes 152A and 154A is increased.

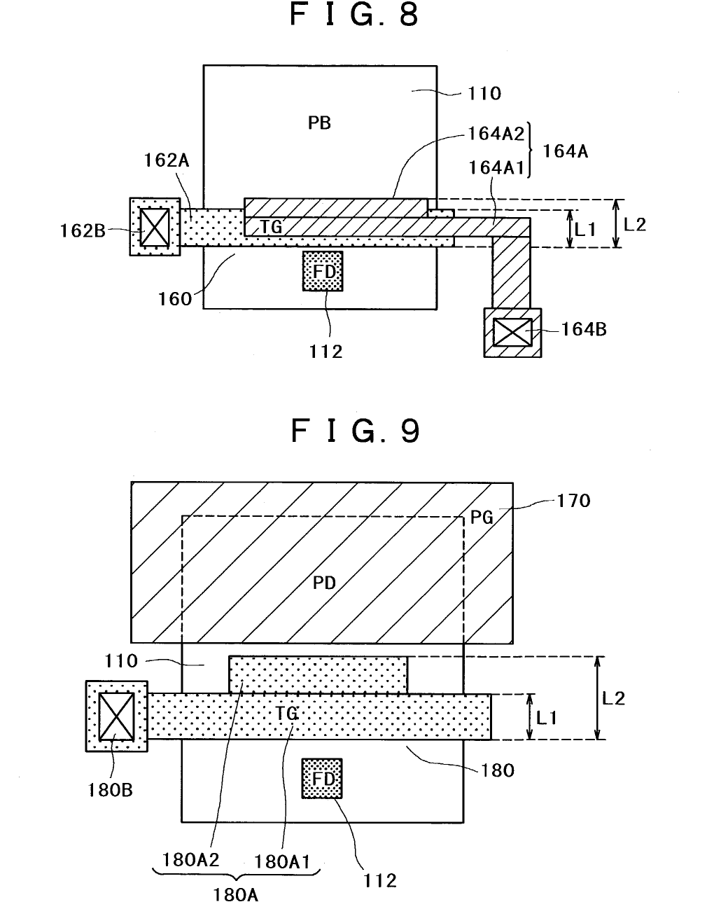

FIG. 8 is a plan view showing an example of an arrangement of elements around a photodiode in a pixel of a solid-state image pickup device according to a fifth embodiment of the present invention. It is to be noted that elements common to those of the example shown in FIG. 2 are denoted by like reference characters and description thereof is omitted.

The solid-state image pickup device of the present embodiment is configured such that two transfer electrodes 162A and 164A of different layers are provided similarly as in the example shown in FIG. 7, and while the transfer electrode 162A (of the lower layer) is similar to the transfer electrode 152A, the other transfer electrode 164A (of the upper layer) has a shape wherein only part thereof extends to the photodiode 110 side.

It is to be noted that end portions of the transfer electrodes 162A and 164A are connected to upper wiring lines (not shown) through contacts 162B and 164B, respectively.

Also in such a configuration as described above, the width in the gate lengthwise direction is expanded from L1 where only the transfer electrode 162A is involved to L2 where the two transfer electrodes 162A and 164A are involved, and the modulation degree by the transfer electrodes 162A and 164A is increased.

FIG. 9 is a plan view showing an example of an arrangement of elements around a photodiode in a pixel of a solid-state image pickup device according to a sixth embodiment of the present invention. It is to be noted that elements common to those of the example shown in FIG. 2 are denoted by like reference characters and description thereof is omitted.

The solid-state image pickup device of the present embodiment includes a photo-gate (PG) 170 in a state (indicated by slanting lines in FIG. 9) wherein it contains part of a photodiode 110.

The photo-gate 170 has a function of binning the surface potential of the photodiode 110 to suppress generation of dark current.

Further, a transfer gate portion 180 is provided at a side portion of the photodiode 110 on which the photo-gate 170 is not provided, and a transfer electrode 180A similar to, for example, that in the first embodiment described hereinabove is provided on the transfer gate portion 180.

In particular, the transfer electrode 180A has a body portion 180A1 and an expanded portion 180A2, and an end portion of the body portion 180A1 is connected to an upper wiring line through a contact 180B.

Also with such a configuration as described above, the width in the gate lengthwise direction is expanded from L1 to L2, and the modulation degree by the transfer electrode 180A is increased and signal charge of the photodiode 110 and the photo-gate 170 can be transferred effectively.

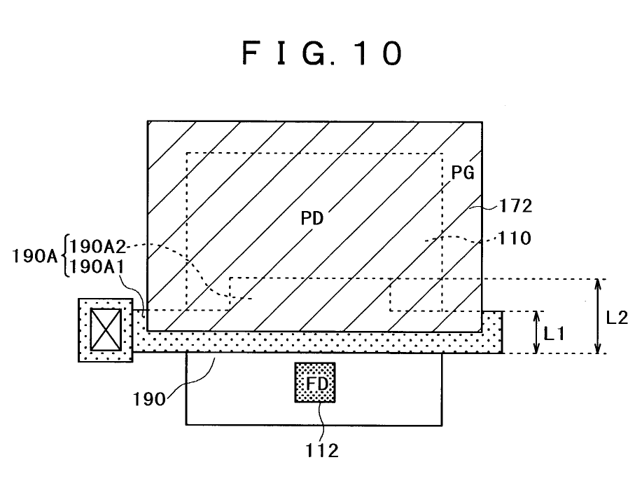

FIG. 10 is a plan view showing an example of an arrangement of elements around a photodiode in a pixel of a solid-state image pickup device according to a seventh embodiment of the present invention. It is to be noted that elements common to those of the example shown in FIG. 2 are denoted by like reference characters and description thereof is omitted.

The solid-state image pickup device of the present embodiment is configured such that an entire photodiode 110 is arranged in a state wherein it is included in a photo-gate (PG) 172 and the photo-gate 172 is disposed in a state wherein part thereof covers a channel region of a transfer gate portion 190.

Further, a transfer electrode 190A similar to, for example, that in the first embodiment described hereinabove is provided on the transfer gate portion 190 in a state wherein it is disposed on the lower side of the photo-gate 172.

In particular, the transfer electrode 190A has a body portion 190A1 and an expanded portion 190A2, and an end portion of the body portion 190A1 is connected to an upper wiring line through a contact 190B.

Also in such a configuration as described above, the width in the gate lengthwise direction is expanded from L1 to L2, and the degree of modulation by the transfer electrode 190A is increased and signal charge of the photodiode 110 and the photo-gate 172 can be transferred effectively.

In the following, eighth to twelfth embodiments of the present invention are described.

The assignee of the present application has proposed, for example, in Japanese Patent Application No. 2001-340440 and so forth, a solid-state image pickup device wherein two gate electrodes of a transfer transistor and a transfer selection transistor disposed in a neighboring relationship with each other in a pixel are formed from electrode films (polycrystalline silicon films) of different layers and the two gate electrode films are arranged in a partly overlapping relationship with each other.

In particular, the solid-state image pickup device includes a transfer transistor 3 which is controlled with a vertical selection signal and a transfer selection transistor formed between FD2 and the transfer transistor 3 in FIG. 1, for controlling the transfer transistor with a horizontal selection signal, and totaling five transistors including the two transistors in addition to an amplification transistor, a reset transistor and a selection transistor described hereinabove are arranged in a pixel.

In such a pixel configuration as described above, the two gate electrodes of the transfer transistor and the transfer selection transistor are arranged in a partly overlapping relationship with each other and channels of the two gate portions are formed continuously while the gate potentials of them are set to negative potentials with respect to well regions in the lower layer to suppress depletion of them and decrease the leak current thereby to realize a solid-state image pickup device which is reduced in noise.

Particularly by setting the gate potential of the transfer transistor on the photodiode side to a negative potential, leak current which has an influence on the photodiode can be suppressed.

Thus, in the following embodiments, examples are described wherein the configuration described hereinabove wherein the gate portion has a belt-like configuration having a plurality of widths in the gate lengthwise direction is applied to such a configuration as just described wherein two gate electrodes are arranged in a partly overlapping relationship with each other such that the characteristics of them are combined to achieve further effective operation and effects.

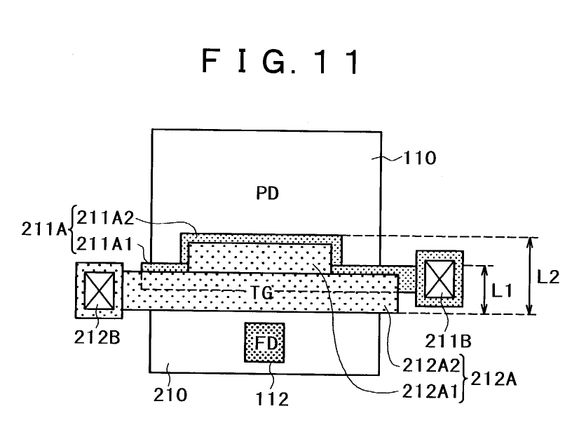

FIG. 11 is a plan view showing an example of an arrangement of elements around a photodiode in a pixel of a solid-state image pickup device according to an eighth embodiment of the present invention. It is to be noted that elements common to those of the example shown in FIG. 2 are denoted by like reference characters and description thereof is omitted.

The solid-state image pickup device of the present embodiment is configured such that, for example, the gate electrode shown in FIG. 2 which includes a body portion and an expanded portion is applied to a gate structure of a two-layer structure of a transfer transistor and a transfer selection transistor.

In particular, referring to FIG. 11, a photodiode 110 and a FD portion 112 are arranged in parallel to each other with a transfer gate portion 210 interposed therebetween. Transfer electrodes 211A and 212A of two layers are arranged above the transfer gate portion 210, and end portions of the transfer electrodes 211A and 212A are connected to upper wiring lines (not shown) through contacts 211B and 212B, respectively.

The transfer electrodes 211A and 212A have a same shape (or similar shapes), and the transfer electrode 211A has a body portion 211A1 and an expanded portion 211A2 provided integrally with each other while the transfer electrode 212A has a body portion 212A1 and an expanded portion 212A2 provided integrally with each other.

Such transfer electrodes 211A and 212A as just described are arranged in a partly overlapping relationship with each other with an insulating film interposed therebetween, and the transfer electrode 211A of the lower layer forms a gate portion of a transfer transistor while the transfer electrode 212A of the upper layer forms a gate portion of a transfer selection transistor.

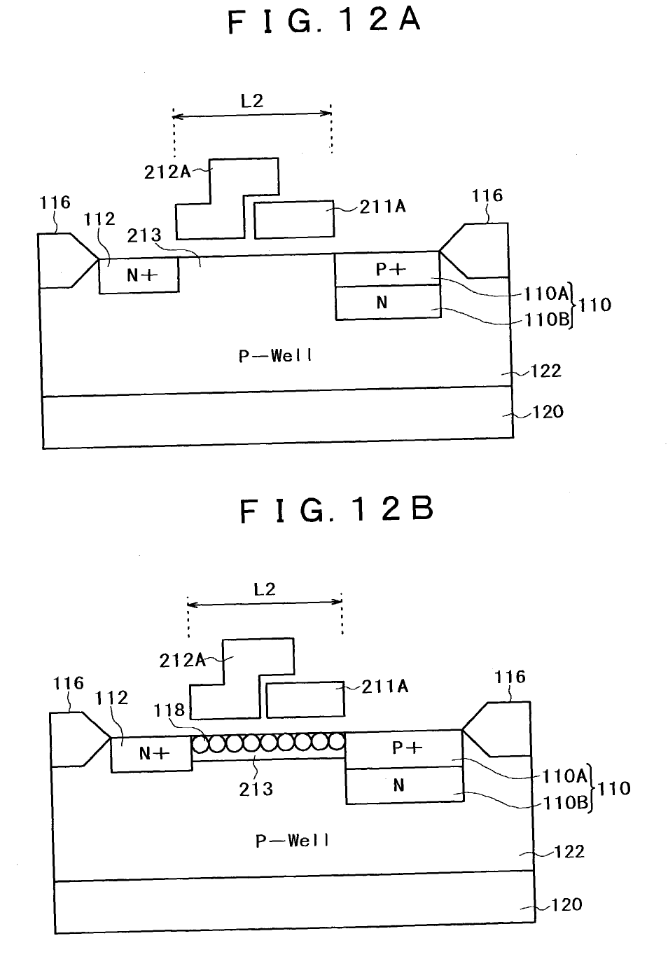

FIGS. 12A and 12B are sectional views showing an element structure in a semiconductor substrate in the element arrangement shown in FIG. 11. It is to be noted that elements common to those of the example shown in FIG. 3 are denoted by like reference characters and description thereof is omitted.

As shown in FIGS. 12A and 12B, a P type well region 122 is formed on a semiconductor substrate (N type silicon substrate) 120, and a photodiode 110 is formed from a P+ layer 110A of an upper layer and an N layer 110B of a lower layer.

Further, a FD portion 112 is formed as an N+ region at a position spaced by a predetermined distance from the photodiode 110.

The P type region between the photodiode 110 and the FD portion 112 forms a continuous gate portion 213 of a transfer transistor and a transfer selection transistor, and transfer electrodes 211A and 212A are arranged on an upper face of the gate portion 213.

It is to be noted that, an element isolation region 116 made of LOCOS or the like is provided around the pixel so that the pixel is electrically isolated from adjacent pixels.

In a state wherein a Low voltage is applied to the transfer electrodes 211A and 212A to place the transfer gate portion 213 to an OFF state, no channel is formed below the transfer electrodes 211A and 212A as shown in FIG. 12A and the portion below the transfer electrodes 211A and 212A remains in the P type.

Then, if a power supply voltage is applied to both of the transfer electrodes 211A and 212A to turn ON the transfer gate 213, signal charge 118 accumulates at portions below the transfer electrodes 211A and 212A as shown in FIG. 12B and an N type channel is formed there.

It is to be noted that, if a power supply voltage is applied to only one of the transfer electrodes 211A and 212A, then the gate portion 213 remains in an OFF state.

In the present example, the gate length is expanded by the transfer electrodes 211A and 212A having the transfer electrodes 211A and 212A at such portions thereof as described above, and consequently, a transfer gate portion whose potential modulation degree can be increased and with which suppression of leak current is realized can be implemented.

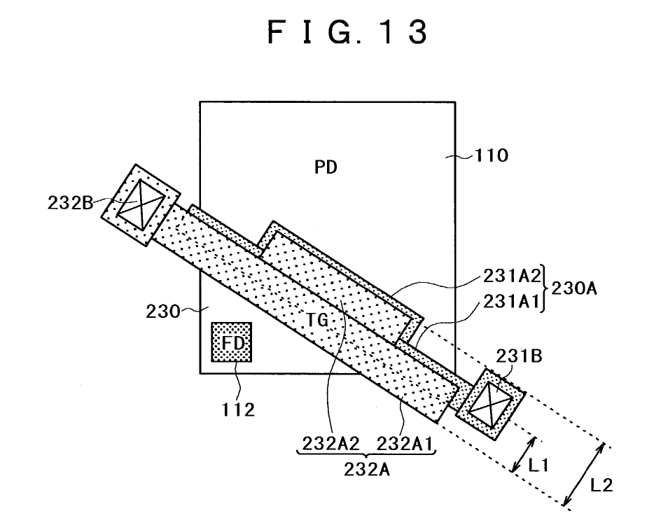

FIG. 13 is a plan view showing an example of an arrangement of elements around a photodiode in a pixel of a solid-state image pickup device according to a ninth embodiment of the present invention. It is to be noted that elements common to those of the example shown in FIG. 2 are denoted by like reference characters and description thereof is omitted.

In the solid-state image pickup device of the present embodiment, an oblique gate electrode which includes a body portion and an expanded portion as shown, for example, in FIG. 5 is applied to a gate electrode of a two-layer structure of a transfer transistor and a transfer selection transistor.

In the solid-state image pickup device of the present embodiment, a FD portion 112 is arranged at an oblique position with respect to a photodiode 110, and transfer electrodes 231A and 232A of a transfer gate portion 230 are arranged in an oblique direction.

The transfer electrodes 231A and 232A are formed in a substantially same shape (or in similar shapes), and the transfer electrode 231A includes a body portion 231A1 and an expanded portion 231A2 provided integrally with each other while the transfer electrode 232A includes a body portion 232A1 and an expanded portion 232A2 provided integrally with each other.

It is to be noted that end portions of the body portions 231A1 and 232A1 of the transfer electrodes 231A and 232A are connected to upper wiring lines (not shown) through contacts 231B and 232B, respectively.

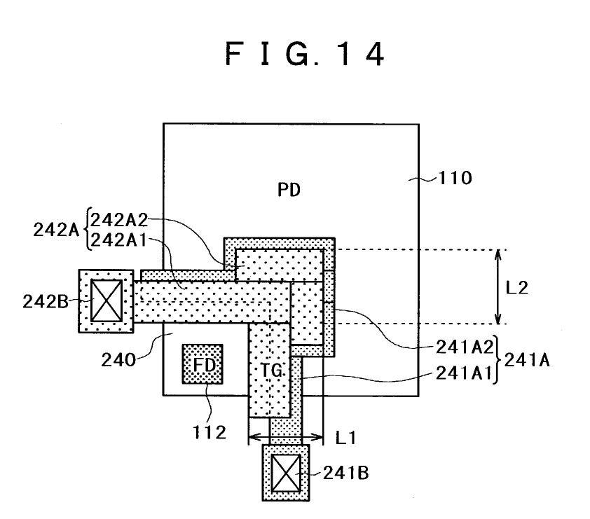

FIG. 14 is a plan view showing an example of an arrangement of elements around a photodiode in a pixel of a solid-state image pickup device according to a tenth embodiment of the present invention. It is to be noted that elements common to those of the example shown in FIG. 2 are denoted by like reference characters and description thereof is omitted.

In the solid-state image pickup device of the present embodiment, a gate electrode which a body portion and an expanded portion and has a bent portion as shown, for example, in FIG. 6 is applied to a gate electrode of a two-layer structure of a transfer transistor and a transfer selection transistor.

In the solid-state image pickup device of the present embodiment, a FD portion 112 is arranged at an oblique position with respect to a photodiode 110, and transfer electrodes 241A and 242A of a transfer gate portion 240 are arranged in a right-angularly bent state such that they surround two side faces of the FD portion 112.

The transfer electrodes 241A and 242A are formed in a same shape (or in similar shapes), and the transfer electrode 241A has an expanded portion 241A2 provided integrally at an outer side corner portion of a body portion 241A1 thereof which is bent at the right angle of 90 degrees, and the transfer electrode 242A includes an expanded portion 242A2 provided integrally at an outer side corner portion of a body portion 242A1 thereof which is bent at the right angle of 90 degrees.

It is to be noted that end portions of the body portions 241A1 and 242A1 of the transfer electrodes 241A and 242A are connected to upper wiring lines (not shown) through contacts 241B and 242B, respectively.

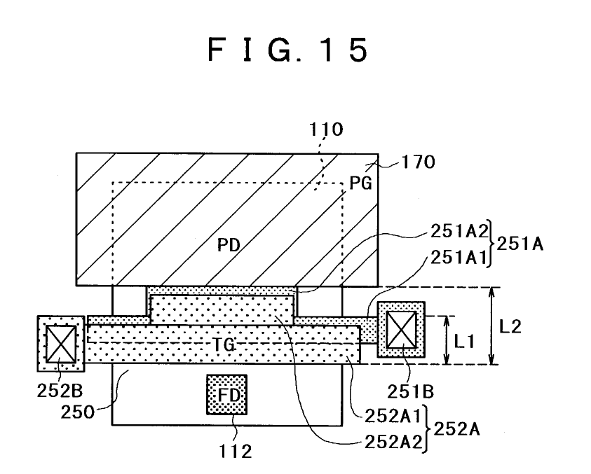

FIG. 15 is a plan view showing an example of an arrangement of elements around a photodiode in a pixel of a solid-state image pickup device according to an eleventh embodiment of the present invention. It is to be noted that elements common to those of the example shown in FIG. 2 are denoted by like reference characters and description thereof is omitted.

In the solid-state image pickup device of the present embodiment, similarly as in the example shown, for example, in FIG. 9, a gate electrode where a photo-gate (PG) 170 is provided in a state (indicated by slanting lines in FIG. 14) wherein it includes part of a photodiode 110 is applied to a gate electrode of a two-layer structure of a transfer transistor and a transfer selection transistor.

Part of signal charge produced by the photodiode 110 is accumulated, and signal charge of the photo-gate 170 is read out together with signal charge of the photodiode 110 by operation of a transfer gate portion 250.

The transfer gate portion 250 is provided on that side of the photodiode 110 on which the photo-gate 170 is not provided, and transfer electrodes 251A and 252A of a two-layer structure similar to that, for example, in the eighth embodiment are provided for the transfer gate portion 250.

The transfer electrodes 251A and 252A are formed in a same shape (or in similar shapes), and the transfer electrode 251A includes a body portion 251A1 and an expanded portion 251A2 provided integrally with each other while the transfer electrode 252A includes a body portion 252A1 and an expanded portion 252A2 provided integrally with each other. Further, end portions of the body portions 251A1 and 252A1 of the transfer electrodes 251A and 252A are connected to upper wiring lines (not shown) through contacts 251B and 252B, respectively.

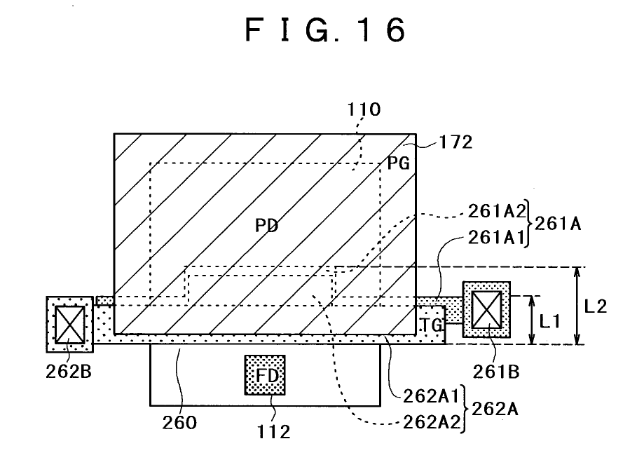

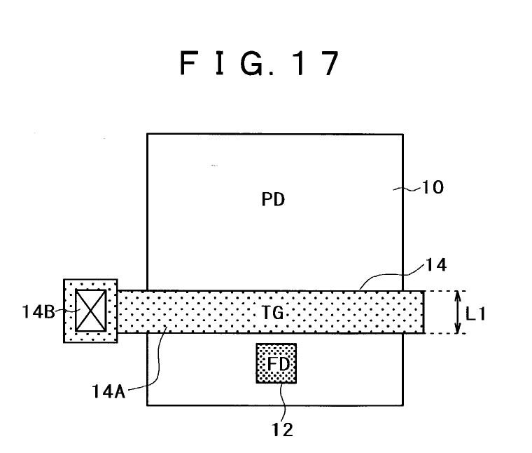

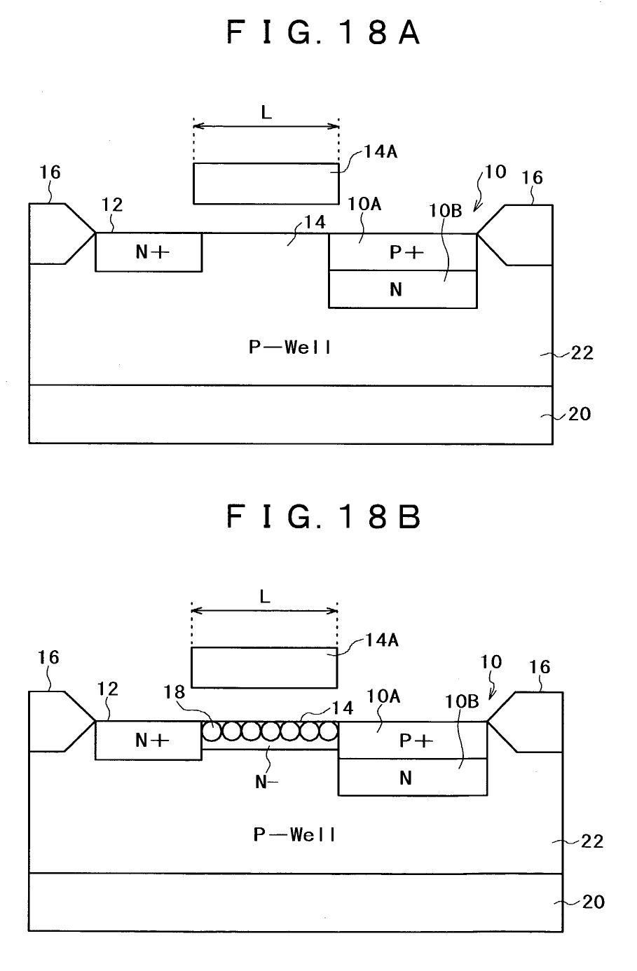

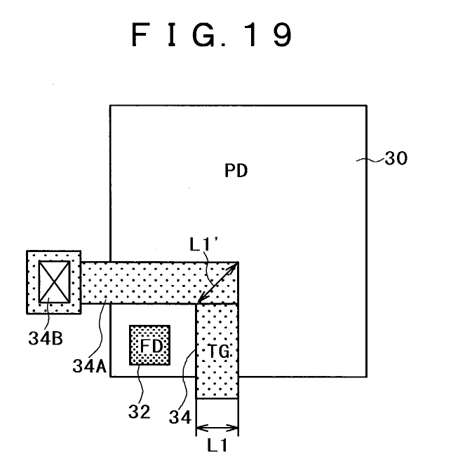

FIG. 16 is a plan view showing an example of an arrangement of elements around a photodiode in a pixel of a solid-state image pickup device according to a twelfth embodiment of the present invention. It is to be noted that elements common to those of the example shown in FIG. 2 are denoted by like reference characters and description thereof is omitted.

In the solid-state image pickup device of the present embodiment, similarly as in the embodiment shown, for example, in FIG. 10, a gate electrode where a photo-gate (PG) 172 is provided in a state wherein it includes an entire photodiode 110 is applied to a gate electrode of a two-layer structure of a transfer transistor and a transfer selection transistor.

In the solid-state image pickup device of the present embodiment, the photodiode 110 is arranged in a state wherein it is entirely included in the photo-gate (GP) 172, and the photo-gate 172 is arranged in a state wherein part thereof overlaps with a channel region of a transfer gate portion 260.

Further, transfer electrodes 261A and 262A are provided on the transfer gate portion 260 in a state wherein they are arranged on the lower side of the photo-gate 172.

The transfer electrodes 261A and 262A are formed in a same shape (or in similar shapes), and the transfer electrode 261A has a body portion 261A1 and an expanded portion 261A2 and an end portion of the body portion 261A1 is connected to an upper wiring line through a contact 261B.

Meanwhile, the transfer electrode 262A has a body portion 261A1 and an expanded portion 262A2, and an end portion of the body portion 261A1 is connected to an upper wiring line through a contact 262B.

It is to be noted that, while, in the embodiments described above, the present invention is applied to the shape of a gate portion of a transfer transistor, the present invention can be applied also to the shape of a gate portion of any other transistor such as, for example, a reset transistor, and also such a configuration as just described shall be included in the scope of the present invention.

Further, the configuration of the solid-state image pickup device to which the present invention is applied is not limit to the embodiments described hereinabove, but the present invention may be applied to any solid-state image pickup device only if a photoelectric conversion element and at least more than one transistor which form a readout circuit for the photoelectric conversion element are included in at least one pixel.

As described above, according to the solid-state image pickup device of the present invention, since a gate portion of a transistor in a pixel has a belt-shaped portion having a plurality of widths in the gate lengthwise direction, the gate length of the gate portion can be increased to increase the potential modulation degree thereby to eliminate residual charge, which arises from an insufficient potential modulation degree, without disturbing so much the numerical aperture of the photoelectric conversion element so much as in a case wherein the entire gate portion is formed in a greater size, and improvement in picture quality and so forth of the solid-state image pickup device can be achieved.

What is claimed is:

1. A solid-state image pickup device having a plurality of pixels comprising:
a photoelectric conversion element;
a transistor formed within said pixel;
wherein a gate electrode of said transistor is a substantially linear member comprised of a first portion having a first width and a second portion having a second width; and
the second width is substantially greater than the first width.

2. A solid-state image pickup device according to claim 1, wherein said transistor is formed between a floating diffusion portion and said photoelectric conversion element.

3. A solid-state image pickup device according to claim 1, wherein said different widths of said gate electrode are each located in a same layer.

4. A solid-state image pickup device according to claim 3, wherein said gate electrode is comprised of poly-Si.

5. A solid-state image pickup device according to claim 1, wherein said transistor is a reset, a selection or an amplifier transistor.

6. A solid-state image pickup device according to claim 2, wherein said gate electrode is formed at an angel other than perpendicular to sides of the photoelectric conversion element.

7. A solid-state image pickup device having a plurality of pixels comprising:
a photoelectric conversion element;
a transistor formed within said pixel;
wherein a gate electrode of said transistor is comprised of two sections that are substantially perpendicular to each other and at least one section is comprised of a first portion having a first width and a second portion having a second width; and
the second width is substantially greater than the first width.

8. A solid-state image pickup device according to claim 2, wherein said gate electrode has a wider portion that extends toward said photoelectric conversion portion.

9. A solid-state image pickup device according to claim 1, wherein said gate electrode is comprised of at least two layers, and each layer is comprised of a different material.

10. A solid-state image pickup device according to claim 9, wherein an upper layer extends toward said photoelectric conversion portion.

11. A solid-state image pickup device according to claim 10, wherein said upper layer includes a plurality of different widths.

12. A solid-state image pickup device according to claim 1, wherein said photoelectric conversion portion has a photo gate electrode.

13. A solid-state image pickup device according to claim 12, wherein said photo gate electrode overlaps with said gate electrode.

14. A solid-state image pickup device according to claim 2, further comprising:
a further transistor formed between said transistor and said floating diffusion portion, and
wherein said transistor and said further transistor have a plurality of different widths.

15. A solid-state image pickup device according to claim 14, wherein a gate electrode of said further transistor is overlapped with that of said transistor.

16. A solid-state image pickup device according to claim 14:
wherein said photoelectric conversion portion has a photo gate electrode; and
wherein said photo gate electrode overlaps with said gate electrodes of said transistors.

17. A solid-state image pickup device comprising:
a photoelectric conversion portion;
a first transistor connected to said photoelectric conversion portion;
a second transistor connected to said first transistor;
a third transistor connected to a node between said first and second transistors; and
wherein at least a gate electrode of one of said first, second and third transistors has a convex portion.

18. A solid-state image pickup device according to claim 17;
wherein a gate electrode of said first transistor has a convex portion; and
said convex portion projects toward said photoelectric conversion portion.

19. A solid-state image pickup device according to claim 18;
wherein said convex portion is comprised of a plurality of different layers; and
wherein said different layers at least partially overlap with each other.

20. A solid-state image pickup device including CMOS circuit comprising:
a semiconductor substrate of a first conductivity type;
a well region of a second conductivity type formed above said semiconductor substrate;
a floating diffusion of said first conductivity type formed in a region above said substrate;
a photoelectric conversion portion comprised of a first impurity region of the first conductivity type and a second impurity region of the second conductivity type whose impurity is higher than that of said first impurity region, formed in said well region;
a transfer transistor formed between said floating diffusion and said photoelectric conversion portion;
wherein a gate electrode of said transfer transistor has a convex portion; and
wherein said convex portion projects toward said photoelectric conversion portion.
